(19) United States
(12) Patent Application Publication
(10) Pub. No.: US 2003/0153193 A1
(43) Pub. Date: Aug. 14, 2003

(54) Etching method

(76) Inventors: Takashi Fuse, Nirasaki-Shi (JP); Machiko Obi, Nirasaki-Shi (JP)

Correspondence Address: SMITH, GAMBRELL & RUSSELL, LLP, 1850 M STREET, N.W., SUITE 800, WASHINGTON, DC, 20036, US

(21) Appl. No.: 10/365,507

(22) Filed: Feb. 13, 2003

(30) Foreign Application Priority Data
Feb. 14, 2002 (JP) 2002-036932

(51) Int. Cl. H01L 21/302

(52) U.S. Cl. 438/710; 438/706

(57) ABSTRACT

This invention is a plasma-etching method including: making into plasma a process gas including C₂F₄ gas that has been introduced into a processing container, maintaining a pressure around an object to be processed arranged in the processing container within a range of 45 to 75 mTorr, and etching an SiO₂ film in the object to be processed through a resist-pattern arranged on the SiO₂ film by using the plasma.

### BACKGROUND OF THE INVENTION

1. Field of the Invention

This invention relates to a plasma-processing method carried out in a manufacturing process of a semiconductor device.

2. Description of the Related Art

Conventionally, gases including C₄F₆, C₄F₈, C₅F₈, and the like are used as an etching gas to etch an SiO₂ film in a substrate to be processed by using plasma through a resist-pattern having holes. When using these gases, there has been a probability that a by-product deposits in the holes as the etching proceeds, whereby an etching rate is decreased to finally stop the etching (to cause a so-called etching stop). Since this etching stop occurs noticeably in proportion as a diameter of the hole becomes smaller in the order of submicron, the above gases may not meet a recent requirement for micro fabrication. In order to avoid this etching stop, there has been made an attempt of making pressure in the processing container low so as to promote dissociation of the gas and increase generation of etching activated species such as CF₂* and the like.

However, there are problems in the above low-pressure process in that it takes time to ignite the plasma, generated plasma is relatively unstable, an etching rate of a resist becomes high, and so on.

### SUMMARY OF THE INVENTION

This invention is intended to solve the above problems. The object of this invention is to provide a plasma-etching method suppressing an etching stop

This invention is a plasma-etching method comprising: making into plasma a process gas including C₂F₄ gas that has been introduced into a processing container, maintaining a pressure around an object to be processed arranged in the processing container within a range of 45 to 75 mTorr, and etching an SiO₂ film in the object to be processed through a resist-pattern arranged on the SiO₂ film by using the plasma.

According to the present invention, by etching the SiO₂ film patterned by the resist-pattern in a relatively high pressure by using the plasma of the process gas including the C₂F₄ gas, an etching stop may be suppressed, so that it is possible to provide the plasma-etching method having a large etching rate, a large etching selectivity over the resist and a small etching rate of the resist.

Alternatively, the present invention is a plasma-etching method comprising: making into plasma a process gas including O₂ gas and C₂F₄ gas that has been introduced into a processing container, and etching an SiO₂ film in an object to be processed arranged in the processing container through a resist-pattern arranged on the SiO₂ film by using the plasma.

According to the present invention, by etching the SiO₂ film patterned by the resist-pattern by using the plasma of the gas including the O₂ gas and the C₂F₄ gas, an etching stop may be suppressed, so that it is possible to provide the plasma-etching method having a large etching rate, a large etching selectivity over the resist and a small etching rate of the resist.

In this case, the above process gas preferably includes Ar. Additionally, a pressure around the object to be processed is preferably maintained within a range of 45 to 500 mTorr. Moreover, a flow ratio of the O₂ gas with respect to the C₂F₄ gas (O₂ flow rate/C₂F₄ flow rate) in the above process gas is preferably set to be 1/10 to 2/5, in particular much preferably set to be 1/10 to 1/5.

### BRIEF DESCRIPTION OF THE DRAWINGS

FIG. 1 is a schematic cross sectional view showing a plasma-etching system applicable to the present invention;

FIG. 2 is a schematic diagram showing a cross section of a target to be etched of an object to be processed;

FIG. 3 is a graph depicting an etching rate of an SiO₂ film and an etching selectivity of the SiO₂ over a resist in relation to a flow ratio of a process gas (O₂/C₂F₄); and

FIG. 4 is a graph depicting an etching rate of the resist in relation to a pressure in the processing container.

### DESCRIPTION OF THE PREFERRED EMBODIMENT

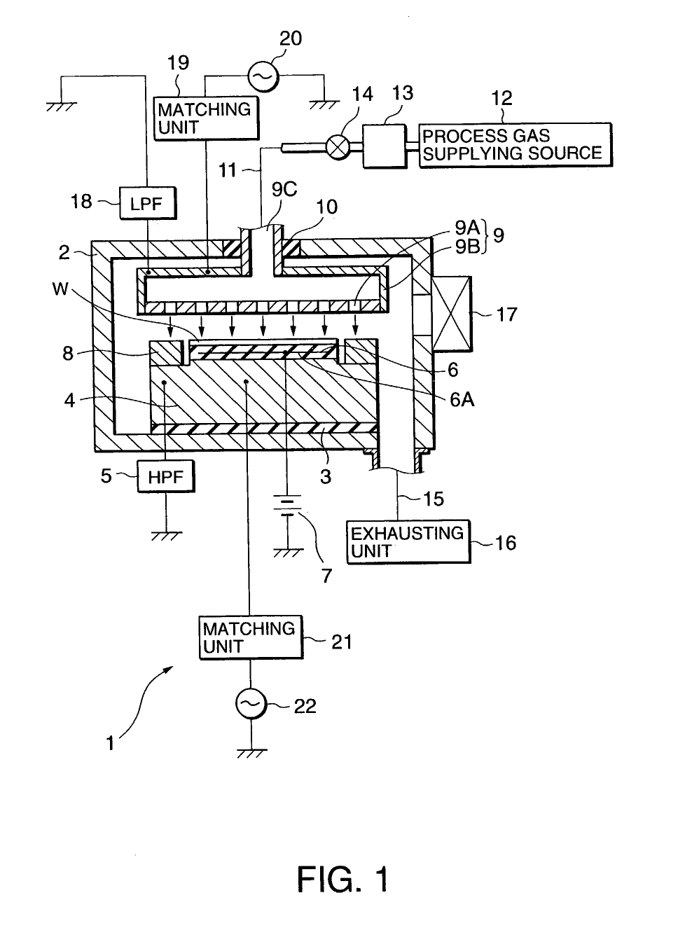

Hereinafter, the present invention will be explained based on embodiments shown in FIG. 1 to FIG. 4.

First, a plasma-etching system used in this embodiment will be described with reference to FIG. 1. As shown in FIG. 1, a processing container 2 of this plasma-etching system 1 is made of metal, for example, aluminum whose surface is oxidized, and is connected to ground for safety.

At a bottom in the processing container 2, a susceptor 4 serving as a lower electrode of parallel plate electrodes is provided through an insulator 3. To this susceptor 4, a high pass filter (HPF) 5 is connected. On the susceptor 4, an electrostatic chuck 6 is provided. On the electrostatic chuck 6, an object to be processed W is placed. The electrostatic chuck 6 is structured in such a manner that an electrode 6A is arranged between insulators, and it absorbs the object to be processed W with electrostatic action when a direct-current voltage is applied from a direct-current power source 7 connected to the electrode 6A. A focus ring 8 surrounding the object to be processed W is arranged at an outer peripheral edge of the susceptor 4. This focus ring 8 is made of Si, SiO₂, and the like, and enhances uniformity of the etching.

Over the susceptor 4, an upper electrode 9 is provided to be opposed to the susceptor 4. This upper electrode 9 includes an electrode plate 9A in a showerhead shape and a supporter 9B for supporting this electrode plate 9A. The supporter 9B is supported at an upper part of the processing container 2 through an insulator 10. At a center portion of the supporter 9B, a gas introducing port 9C is provided. To this gas introducing port 9C, a process gas supplying source 12 is connected through a gas supplying pipe 11. The gas supplying pipe 11 is provided with a massflow controller 13 and a valve 14 in this order from upstream to downstream.

On the other hand, an exhausting pipe 15 is connected at the bottom of the processing container 2. To this exhausting pipe 15, an exhausting unit 16 is connected. Furthermore, there is arranged a gate valve 17 at a transferring port on a side wall of the processing container. The object to be processed W is adapted to be transferred between the processing container 2 and an adjacent load lock chamber (not shown) through the transferring port whose gate valve is opened. To the upper electrode 9, connected are a low pass filter (LPF) 18 and a first high-frequency electric power supply 20 through a matching unit 19. To the susceptor 4 which serves as the lower electrode, connected is a second high-frequency electric power supply 22 through a matching unit 21.

Next, an embodiment of the present invention will be explained in which an SiO₂ film in an object to be processed W is etched by using plasma utilizing the above plasma-etching system 1. After the gate valve 17 is opened, the object to be processed W is transferred into the processing container 2 to be placed on the electrostatic chuck 6. Then, after the gate valve 17 is closed and the pressure in the processing container 2 is reduced by the exhausting unit 16, the valve 13 is opened and O₂ gas, C₂F₄ gas, and Ar gas are supplied from the process gas supplying source 12. High-frequency electric power is applied to the upper electrode 9 and the susceptor 4 which also serves as the lower electrode respectively from the first and second high-frequency electric power supply 20 and 22, and a process gas (etching gas) is made into plasma to etch the SiO₂ film in the object to be processed W. On the other hand, around the time when the respective high-frequency electric power is applied to the upper and lower electrodes 4 and 9, the direct-current voltage is applied to the electrode 6A in the electrostatic chuck 6 from the direct-current power source 7, whereby the object to be processed W is absorbed on the electrostatic chuck 6 with electrostatic action. When an end-point detector (not shown) detects a predetermined luminescence intensity, the etching is finished.

By carrying out the above operation, it is possible to etch the SiO₂ film while suppressing the etching stop even under the relatively high pressure where the plasma exists stably. Due to O₂ inclusion in the process gas, an etching selectivity of the SiO₂ film over the resist (SiO₂ etching rate/resist etching rate) is enhanced.

Preferably, when the etching gas includes the C₂F₄ gas, a pressure around the object to be processed arranged in the processing container is maintained within a range of 45 mTorr to 75 mTorr. Moreover, when the etching gas further includes the O₂ gas, the pressure around the object to be processed arranged in the processing container is preferably maintained within a range of 45 mTorr to 500 mTorr. This is because the resist etching rate may be increased sharply when the pressure is lower than 45 mTorr, and the etching stop may be caused when the pressure is higher than 500 mTorr. Additionally, a diluting gas such as Ar may be added to the etching gas including the C₂F₄ gas and the etching gas including both of the O₂ gas and the C₂F₄ gas. A flow ratio of the O₂ gas with respect to the C₂F₄ gas (O₂ flow rate/C₂F₄ flow rate) is preferably set to be 1/10 to 2/5, more preferably set to be 1/10 to 1/5. This is because the etching selectivity of the SiO₂ film over the resist may be decreased when the flow ratio is more than 2/5, and the etching rate of the SiO₂ may be decreased sharply when the flow ratio is less than 1/10.

### EXAMPLE 1

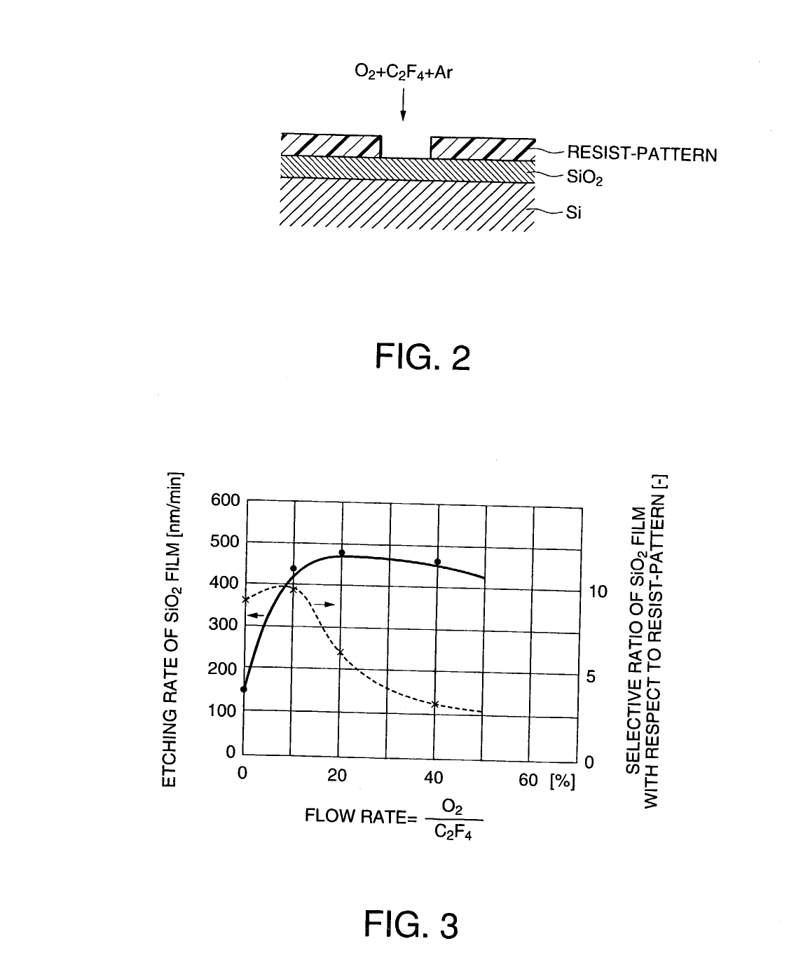

In this example, by using the plasma etching system 1 shown in FIG. 1, under the following condition, an SiO₂ film on an Si film in an object to be processed was etched through a resist-pattern as shown in FIG. 2, and an etching rate of the SiO₂ film and an etching selectivity of the SiO₂ film over the resist were measured. In FIG. 3, the etching rate of the SiO₂ film is shown in full line and the etching selectivity of the SiO₂ film over the resist is shown in dotted line.

[Etching Condition]

1. Frequency of the first high-frequency electric power supply: 60 MHz

2. First high-frequency electric power: 1000W

3. Frequency of the second high-frequency electric power supply: 2 MHz

4. Second high-frequency electric power: 2000W

5. Temperature of the susceptor; 10° C.

6. Pressure around an object to be processed arranged in the processing container: 75 mTorr

7. Temperature of a wafer; 0° C.

8. Flow rate of the etching gas: A C₂F₄ flow rate is set to be 50 sccm and an Ar flow rate is set to be 400 sccm, while an O₂ flow rate is changed to be 0, 5, 10, and 20 sccm.

According to the result shown in FIG. 3, it is recognized that if the O₂ gas is not added to the C₂F₄ gas, the etching rate of the SiO₂ is low, but the etching selectivity of the SiO₂ film over the resist is high. It is also recognized that the etching rate of the SiO₂ film is increased by adding the O₂ gas to the C₂F₄ gas, while the selectivity of the SiO₂ film over the resist is decreased by excessively adding the O₂ gas to the C₂F₄ gas.

### EXAMPLE 2

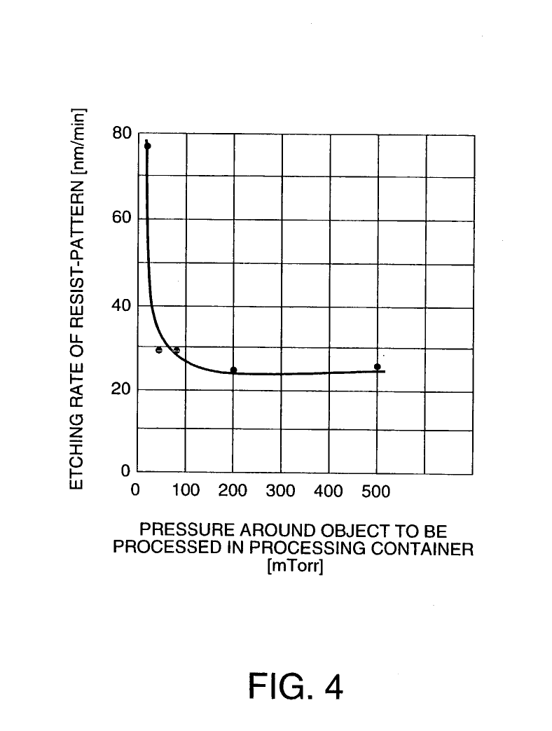

In this example, by using an O₂ gas, a C₂F₄ gas and an Ar gas as an etching gas, an SiO₂ film was etched while changing a pressure around an object to be processed arranged in the processing container 2 (refer to FIG. 2) to 15, 45, 75, 200 and 500 mTorr. At this time, an etching rate of a resist was measured. The result is shown in FIG. 4. In accordance with the result shown in FIG. 4, it is recognized that when the pressure around the object to be processed arranged in the processing container is low at 15 mTorr, the etching rate of the resist may be increased.

Furthermore, in accordance with another experiment using the O₂ gas, the C₂F₄ gas and the Ar gas as the etching gas, it could be found that the etching stop is caused noticeably when the pressure around the object to be processed W arranged in the processing container 2 is higher than 500 mTorr.

Next, an etching method of an antireflection film using the plasma etching system 1 will be explained. An organic antireflection film is provided on an object to be processed, and a resist is further applied thereon. Thereafter, the resist is exposed to an ArF excimer laser and developed to become a resist-pattern. Then, using this resist-pattern as a mask, the antireflection film is etched by using plasma. As an etching gas, a gas of only CF₄ gas, or a gas of CF₄ gas added with O₂ gas (flow ratio is about CF₄:O₂=95:5) may be used. When observing the resist after etching, there was not seen either surface roughness or a striation.

1. A plasma-etching method comprising:
making into plasma a process gas including C₂F₄ gas that has been introduced into a processing container,
maintaining a pressure around an object to be processed arranged in the processing container within a range of 45 to 75 mTorr, and
etching an SiO₂ film in the object to be processed through a resist-pattern arranged on the SiO₂ film by using the plasma.

2. A plasma-etching method comprising:
making into plasma a process gas including O₂ gas and C₂F₄ gas that has been introduced into a processing container, and
etching an SiO₂ film in an object to be processed arranged in the processing container through a resist-pattern arranged on the SiO₂ film by using the plasma.

3. A plasma-etching method according to claim 2, wherein
the process gas includes Ar.

4. A plasma-etching method according to claim 3, wherein
a pressure around the object to be processed is maintained within a range of 45 to 500 mTorr.

5. A plasma-etching method according to claim 4, wherein
a flow ratio of the O₂ gas with respect to the C₂F₄ gas in the process gas (O₂ flow rate/C₂F₄ flow rate) is set to be 1/10 to 2/5.

6. A plasma-etching method according to claim 4, wherein
a flow ratio of the O₂ gas with respect to the C₂F₄ gas in the process gas (O₂ flow rate/C₂F₄ flow rate) is set to be 1/10 to 1/5.

7. A plasma-etching method according to claim 3, wherein
a flow ratio of the O₂ gas with respect to the C₂F₄ gas in the process gas (O₂ flow rate/C₂F₄ flow rate) is set to be 1/10 to 2/5.

8. A plasma-etching method according to claim 3, wherein
a flow ratio of the O₂ gas with respect to the C₂F₄ gas in the process gas (O₂ flow rate/C₂F₄ flow rate) is set to be 1/10 to 1/5.

9. A plasma-etching method according to claim 2, wherein
a pressure around the object to be processed is maintained within a range of 45 to 500 mTorr.

10. A plasma-etching method according to claim 9, wherein
a flow ratio of the O₂ gas with respect to the C₂F₄ gas in the process gas (O₂ flow rate/C₂F₄ flow rate) is set to be 1/10 to 2/5.

11. A plasma-etching method according to claim 9, wherein
a flow ratio of the O₂ gas with respect to the C₂F₄ gas in the process gas (O₂ flow rate/C₂F₄ flow rate) is set to be 1/10 to 1/5.

12. A plasma-etching method according to claim 2, wherein
a flow ratio of the O₂ gas with respect to the C₂F₄ gas in the process gas (O₂ flow rate/C₂F₄ flow rate) is set to be 1/10 to 2/5.

13. A plasma-etching method according to claim 2, wherein a flow ratio of the O₂ gas with respect to the C₂F₄ gas in the process gas (O₂ flow rate/C₂F₄ flow rate) is set to be 1/10 to 1/5.
